(19) United States
(12) Patent Application Publication
(10) Pub. No.: US 2012/0146059 A1
(43) Pub. Date: Jun. 14, 2012

(54) Organic light emitting diode display

(75) Inventors: Jung-Woo Moon, Yongin-City (KR); Hoon Kim, Yongin-City (KR); Kie Hyun Nam, Yongin-City (KR)

(73) Assignee: Samsung Mobile Display Co., Ltd., Yongin-City (KR)

(21) Appl. No.: 13/200,382

(22) Filed: Sep. 23, 2011

(30) Foreign Application Priority Data
Dec. 9, 2010 (KR) 10-2010-0125725

(51) Int. Cl. H01L 33/60

(52) U.S. Cl. 257/88; 257/E33.06

(57) ABSTRACT

An organic light emitting diode (OLED) display includes: a substrate; an organic light emitting diode disposed on the substrate; a sealing member sealed with the substrate, interposing the organic light emitting diode therebetween; a pad portion disposed on the substrate, corresponding to an edge of the sealing member, and electrically connected with the organic light emitting diode; a conductive line portion formed on the sealing member and/or on the substrate, and applied with driving power supplied to the organic light emitting diode; and a conductive connection portion directly connecting the pad portion and the conductive line portion.

### CLAIM OF PRIORITY

This application makes reference to, incorporates the same herein, and claims all benefits accruing under 35 U.S.C §119 from an application entitled earlier filed in the Korean Intellectual Property Office on 9 Dec. 2010 (which was duly assigned Serial No. 10-2010-0125725 by that Office.

### BACKGROUND OF THE INVENTION

1. Field of the Invention

The present invention relates to an organic light emitting diode (OLED) display. More particularly, the described technology relates generally to an OLED display including a sealing member having a metal layer.

2. Description of the Related Art

Display devices display images and recently, an organic light emitting diode display has been in the spotlight.

The organic light emitting diode display has a self-emitting characteristic and needs not to a separate light source such that a thickness and a weight are decreased, unlike a liquid crystal display. In addition, the organic light emitting diode display has high-grade characteristics such as low power consumption, high luminance, high reaction speed, and the like.

A conventional OLED display includes an organic light emitting diode and a substrate where the organic light emitting diode is located.

Recently, the number of organic light emitting diodes on the substrate is increased as the OLED display is increased in size, and accordingly, much more driving power is required to drive the organic light emitting diode.

The above information disclosed in this Background section is only for enhancement of understanding of the background of the described technology and therefore it may contain information that does not form the prior art that is already known in this country to a person of ordinary skill in the art

### SUMMARY OF THE INVENTION

The described technology has been made in an effort to provide an OLED display that can supply sufficient driving power to an organic light emitting diode increased in size.

One aspect of the embodiment provides an OLED display including: a substrate; an organic light emitting diode disposed on the substrate; a sealing member sealed with the substrate, interposing the organic light emitting diode therebetween; a pad portion disposed on the substrate, corresponding to an edge of the sealing member, and electrically connected with the organic light emitting diode; a conductive line portion formed on the sealing member and/or on the substrate, and applied with driving power supplied to the organic light emitting diode; and a conductive connection portion directly connecting the pad portion and the conductive line portion.

The organic light emitting diode may include a first electrode disposed on the substrate, an organic emission layer disposed on the first electrode, and a second electrode disposed on the organic emission layer, and the pad portion may include a first sub-pad portion electrically connected with the first electrode and a second sub-pad portion electrically connected with the second electrode.

The first pad-portion and the second par-portion may be respectively provided in plural, and the plurality of first sub-pad portions and the plurality of second sub-pad portions may respectively alternate each other in arrangement corresponding to the entire edges of the sealing member.

The first electrode may be light transflective and the second electrode may be light reflective.

The conductive line portion may include a first sub-conductive line portion connected with the first sub-pad portion, interposing the conductive connection portion therebetween and a second sub-conductive line portion connected with the second sub-pad portion, interposing the conductive connection portion therebetween.

The first sub-conductive line portion and the second sub-conductive line portion may be formed on the sealing member, and the conductive connection portion may be extended to the upper portion of the substrate from the sealing member through an edge of the sealing member.

The OLED display may further include a first driver disposed on the sealing member and being connected with the first and second sub-conductive line portions, supplying first power as the driving power to the first sub-conductive line portion, and supplying second power as the driving power to the second sub-conductive line portion.

At least one of the first and second sub-conductive line portions may be formed on the sealing member and the other may be formed on the substrate.

The first sub-conductive line portion is formed on the sealing member and the second sub-conductive line portion is formed on the substrate, and the conductive connection portion may include a first sub-conductive connection portion extended to the upper portion of the substrate through an edge of the sealing member from the sealing member and connecting the first sub-conductive line portion and the first sub-pad portion and a second sub-conductive connection portion connecting the second sub-conductive line portion and the second sub-pad portion on the substrate.

The OLED display further includes a first power supply portion disposed on the substrate the substrate, a second power supply portion disposed on the substrate, and a second driver supplying first power as the driving power to the first power supply portion and supplying second power as the driving power to the second power supply portion. The conductive connection portion may further include a third sub-conductive connection portion extended to the upper portion of the substrate from the sealing member through an edge of the sealing member and connecting the first sub-conductive line portion and the first power supply portion and a fourth sub-conductive connection portion connecting the second sub-conductive line portion and the second power supply portion on the substrate.

The sealing member may include a metal layer disposed on the organic light emitting diode, an insulation layer disposed between the metal layer and the conductive line portion, and an adhesive layer disposed between the metal layer and the organic light emitting diode.

According to one of the abode-stated exemplary embodiments, an OLED display that can supply sufficient driving power to an organic light emitting diode increased in size.

### BRIEF DESCRIPTION OF THE DRAWINGS

A more complete appreciation of the present invention, and many of the attendant advantages thereof, will become readily apparent as the same becomes better understood by reference to the following detailed description when considered in conjunction with the accompanying drawings in which like reference symbols indicate the same or similar components, wherein:

FIG. 1 is a top plan view of an organic light emitting diode (OLED) display according to a first exemplary embodiment;

FIG. 2 is a cross-sectional view of the OLED display, taken along the line II-II of FIG. 1 according to the first exemplary embodiment;

FIG. 3 is a circuit diagram of a pixel in the OLED display according to the first exemplary embodiment;

FIG. 4 is a cross-sectional view of a part of the pixel of the OLED display according to the first exemplary embodiment;

FIG. 5 is a top plan view of an OLED display according to a second exemplary embodiment; and

FIG. 6 is a cross-sectional view of the OLED display, taken along the line VI-VI of FIG. 5 according to the second exemplary embodiment.

### DETAILED DESCRIPTION OF THE INVENTION

The present invention will be described more fully hereinafter with reference to the accompanying drawings, in which exemplary embodiments of the invention are shown. As those skilled in the art would realize, the described embodiments may be modified in various different ways, all without departing from the spirit or scope of the present invention.

In order to clarify the present invention, parts that are not connected to the description will be omitted, and the same elements or equivalents are referred to as the same reference numerals throughout the specification.

In various exemplary embodiments, the same reference numerals are used for the elements having the same configuration and will be representatively described in a first exemplary embodiment, and in other exemplary embodiments, only elements different from those of the first exemplary embodiment will be described.

In addition, the size and thickness of each component shown in the drawings are arbitrarily shown for understanding and ease of description, but the present invention is not limited thereto.

In the drawings, the thickness of layers, films, panels, regions, etc., are exaggerated for clarity. In the drawings, for understanding and ease of description, the thicknesses of some layers and areas are exaggerated. It will be understood that when an element such as a layer, film, region, or substrate is referred to as being “on” another element, it can be directly on the other element or intervening elements may also be present.

In addition, unless explicitly described to the contrary, the word “comprise” and variations such as “comprises” or “comprising”, will be understood to imply the inclusion of stated elements but not the exclusion of any other elements. Further, throughout the specification, “on” implies being positioned above or below a target element and does not imply being necessarily positioned on the top on the basis of a gravity direction.

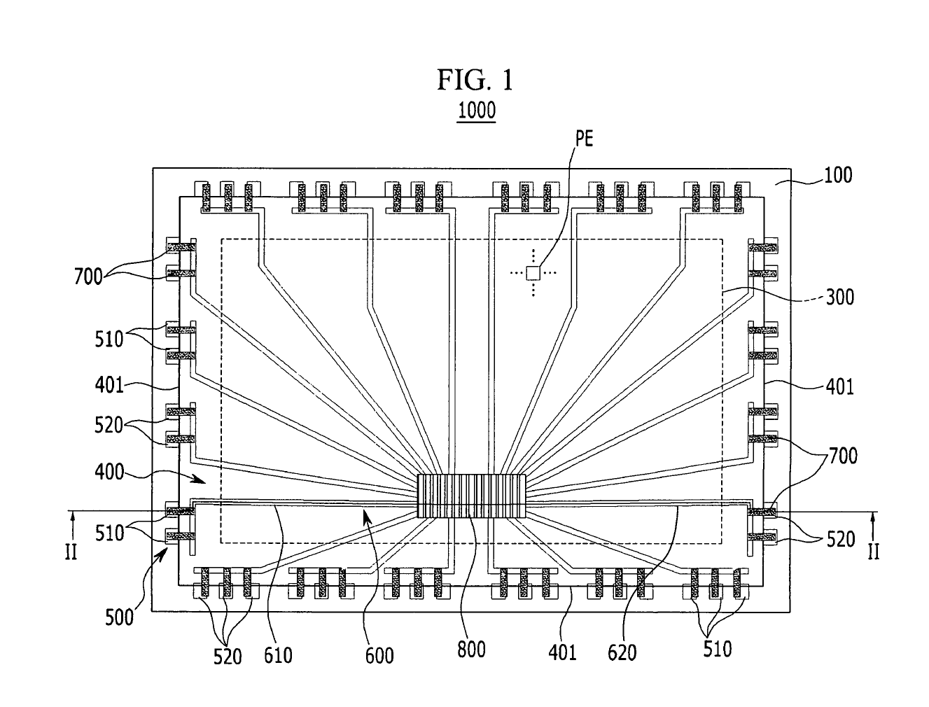

Hereinafter, an organic light emitting diode (OLED) display according to a first exemplary embodiment will be described with reference to FIG. 1 to FIG. 4.

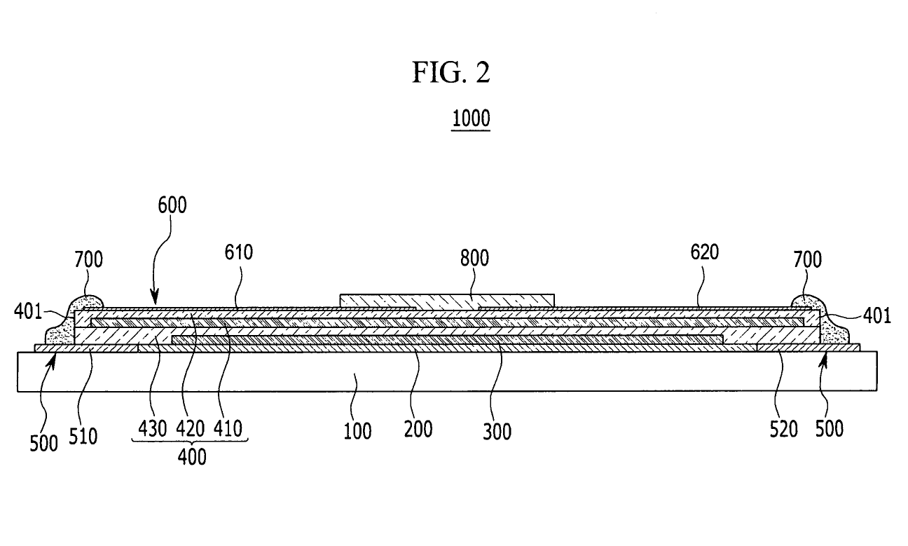

FIG. 1 is a top plan view of an OLED display according to the first exemplary embodiment. FIG. 2 is a cross-sectional view of FIG. 1, taken along the line II-II.

As shown in FIG. 1 and FIG. 2, an OLED display 1000 according to the first exemplary embodiment includes a substrate 100, a wire portion 200, an organic light emitting diode 300, a sealing material 400, pad portion 500, a conductive line portion 600, conductive connection portions 700, a first driver 800, and a plurality of pixels PE.

The substrate 100 is formed with a light transflective substrate made of glass, quartz, ceramic, or plastic. The wire portion 200 and the organic light emitting diode 300 are disposed on the substrate 100, and substrate 100 is arranged opposite to the sealing material 400, interposing the wire portion 200 and the organic light emitting diode 300 therebetween.

As shown in FIG. 1 and FIG. 2, the substrate 100 and the sealing material 400 are sealed to each other, interposing the organic light emitting diode 300 therebetween, and the substrate 100 and the sealing material 400 protect the wire portion 200 and the organic light emitting diode 300 from external interference. The sealing material 400 and includes a metal layer 410, an insulation layer 420, and an adhesive layer 430.

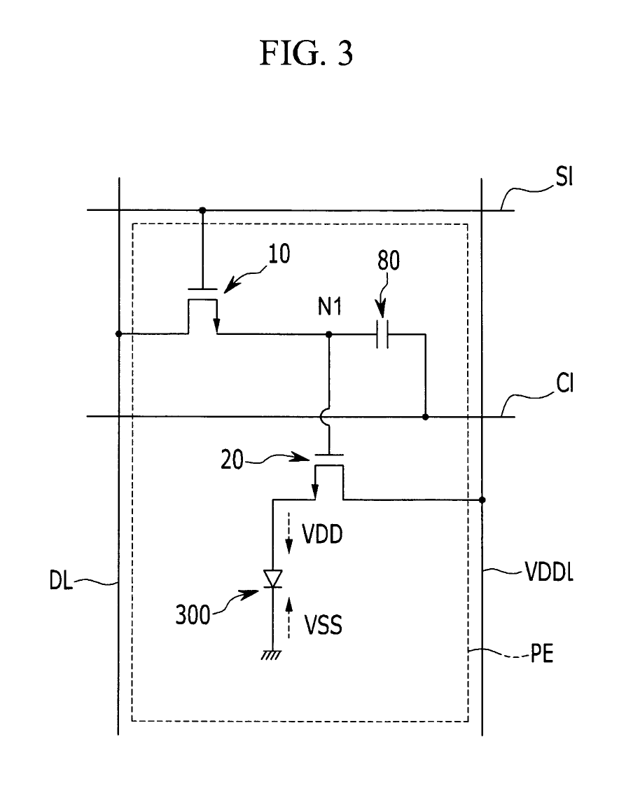

The wire portion 200 includes first and second thin film transistors 10 and 20 (shown in FIG. 3), and drives the organic light emitting diode 300 by transmitting a signal thereto. The organic light emitting diode 300 emits light according to the signal transmitted from the wire portion 200.

The organic light emitting diode 300 is disposed on the wire portion 200.

The organic light emitting diode 300 is disposed on the substrate 100, and receives a driving signal from the wire portion 200 and displays an image according to the received signal. Further features of FIGS. 1 and 2 will be described in more detail later.

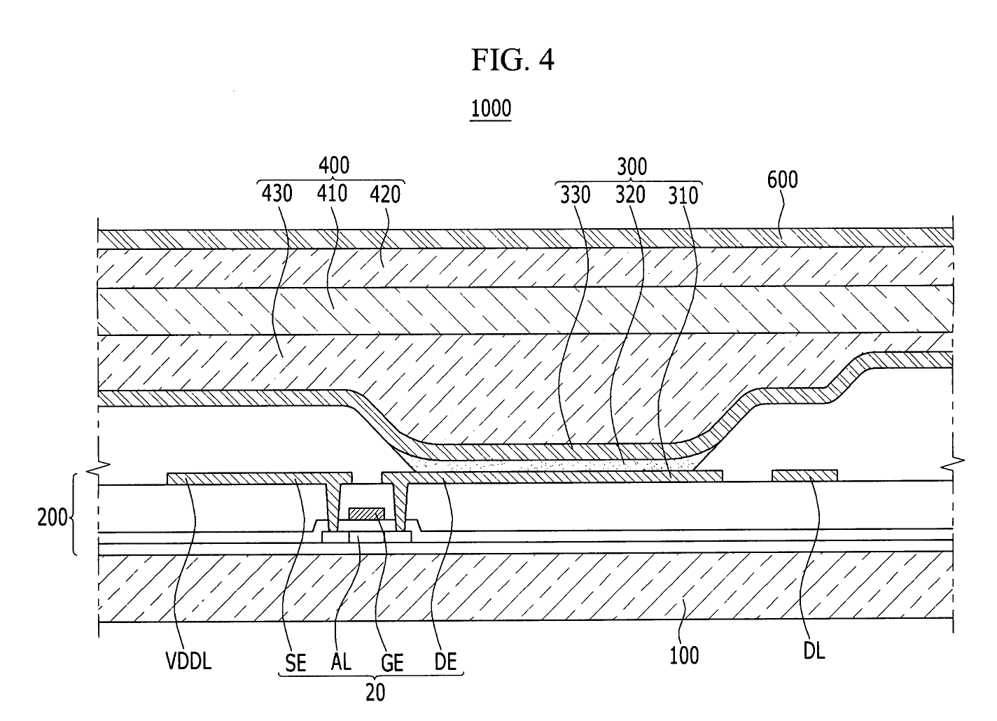

Hereinafter, a structure of the wire portion 200 and the organic light emitting diode 300 of the OLED display 1000 according to the first exemplary embodiment will be described with reference to FIG. 3 and FIG. 4.

FIG. 3 is a circuit diagram of a pixel of the OLED display according to the first exemplary embodiment. In FIG. 3, the pixel PE implies the minimum unit displaying an image, and the OLED display 1000 displays an image using a plurality of pixels PE.

As shown in FIG. 3, in the OLED display 1000 according to the first exemplary embodiment, each pixel PE has a 2Tr-1Cap structure with an organic light emitting diode 300, the first thin film transistor 10, the second thin film transistor 20, and a capacitor 80, and the first thin film transistor 10, the second thin film transistor 20, and the capacitor 80 form the wire portion 200. Meanwhile, the pixel PE has the 2Tr-1Cap structure in the first exemplary embodiment, but it may be variously structured such that three or more thin film transistors and two or more capacitors are provided at one pixel PE together with a separate wire. The additional thin film transistor and capacitors form a compensation circuit (not shown).

The compensation circuit improves uniformity of the organic light emitting diode 300 formed at each pixel PE such that it suppresses deviation of the display quality. In general, the compensation circuit includes two to eight thin film transistors (not shown).

The organic light emitting diode 300 includes an anode being a hole injection electrode, a cathode being an electron injection electrode, and an organic emission layer disposed between the anode and the cathode.

The first and second thin film transistors 10 and 20 included in the wire portion 200 (FIG. 4) respectively include gate electrodes, semiconductor layers, source electrodes, and drain electrodes.

FIG. 3 illustrates scan (gate) lines SL, data lines DL, common power lines VDDL, and capacitor lines CL, but the structure of the pixel PE of the display panel 100 included in the OLED display 1000 is not limited thereto. Thus, the capacitor lines CL may be omitted as necessary.

A source electrode of the first thin film transistor 10 is connected to the data line DL and a gate electrode of the first thin film transistor 10 is connected to the scan line SL. In addition, a drain electrode of the first thin film transistor 10 is connected to the capacitor line CL through the capacitor 80. A node N1 is formed between the drain electrode of the first thin film transistor 10 and the capacitor 80, and a gate electrode of second thin film transistor 20 is connected thereto. Further, the common power line VDDL is connected to a source electrode of the second thin film transistor 20, and an anode of the organic light emitting diode 300 is connected to a drain electrode of the second thin film transistor 20.

The first thin film transistor 10 is used as a switch to select a pixel PE for light emission. When the first thin film transistor 10 is instantaneously turned on, the capacitor 80 is charged and the amount of charge charged in this case is proportional to the potential of a voltage applied from the data line DL. In addition, when a signal that increases a voltage for each frame period is input to the capacitor line CL while the first thin film transistor 10 is being turned off, a gate potential of the second thin film transistor 20 is increased along a voltage applied through the capacitor line CL with reference to the potential charged in the capacitor 80. When the gate potential is higher than a threshold voltage, the second thin film transistor 20 is turned on. Then, first power VDD that is driving power supplied through the conductive line portion, the conductive connection portion, and the pad portion from the first driver is applied to the anode of the organic light emitting diode 300 through the common power line VDDL and the second thin film transistor 20.

Further, second power VSS that is driving power supplied through the conductive line portion, the conductive connection portion, and the pad portion from the first driver is supplied to the cathode of the organic light emitting diode 300, and the organic light emitting diode 300 emits light by the first power VDD applied to the anode of the organic light emitting diode 300 through the second thin film transistor 20 and the second power VSS applied to the cathode of the organic light emitting diode 300.

The structure of the pixel PE is not limited to as above-described, but may be variously modified provided that such modifications can be easily appreciated and made by a person skilled in the art.

FIG. 4 is a cross-sectional view partially illustrating a pixel of the OLED display according to the first exemplary embodiment. FIG. 4 mainly illustrates the second thin film transistor 20 and the organic light emitting diode 300 of the OLED display 1000 according to the first exemplary embodiment.

As shown in FIG. 4, the wire portion 200 includes the common power line VDDL, the data line DL, and the second thin film transistor 20 having a semiconductor layer AL, a gate electrode GE, a source electrode SE, and a drain electrode DE.

The second thin film transistor 20 receives the first power that is the driving power for light emission of the organic light emitting diode 300 in the selected pixel PE from the common power line VDDL and applies the received power to a first electrode 310 of the organic light emitting diode 300 through the source electrode SE, the semiconductor layer AL, and the drain electrode DE. The first electrode 310 of the organic light emitting diode 300 is extended from the drain electrode DE, and the drain electrode DE and the first electrode 310 are connected to each other.

The organic light emitting diode 300 includes the first electrode 310, the organic emission layer 320 disposed on the first electrode 310, and a second electrode 330 disposed on the organic emission layer 320.

The first electrode 310 is an anode that is a hole injection electrode, and the second electrode 330 is a cathode that is an electron injection electrode. However, the first exemplary embodiment is not limited thereto. That is, the first electrode 310 may become a negative electrode and the second electrode 330 may become a positive electrode according to a driving method of the OLED display 1000. When the first power that is the driving power supplied from the first driver through the conductive line portion 600, the conductive connection portion, and the pad portion is supplied to the first electrode 310 by the second thin film transistor 20 and the second power that is the driving power supplied from the first driver through the conductive line portion 600, the conductive connection portion, and the pad portion is supplied to the second electrode 330, holes and electrodes are injected into the organic emission layer 320 respectively from the first and second electrodes 310 and 330, and emission of light from the organic emission layer 320 is made when the excitons being the combinations of the injected holes and electrodes drop from the excited state to the ground state.

Further, the first electrode 310 includes a single layered or multi-layered light transflective conducting material including at least one of indium tin oxide (ITO) and indium zinc oxide (IZO), and the second electrode 330 includes a single-layered or multi-layered light reflective conducting material including at least one of aluminum Al and silver Ag, and accordingly light emitted from the organic emission layer 320 is irradiated to a direction where the first electrode 310 and the substrate 100 are located.

The organic emission layer 320 is a layer where the holes and the electrodes respectively injected from the first electrode 310 and the second electrode 330 are combined, and may emit light of red, greed, or blue.

The substrate 100 and the sealing material 400 protect the wire portion 200 and the organic light emitting diode 300 from external interference. As shown in FIG. 4, the sealing material 400 is sealed with the substrate 100, interposing the organic light emitting diode 300 therebetween, and includes a metal layer 410, an insulation layer 420, and an adhesive layer 430.

As described, the organic light emitting diode 300 in the OLED display 1000 according to the first exemplary embodiment emits light toward a direction of the first substrate 100. That is, the OLED display 1000 is a bottom emission type display.

As described, the first and second power and are supplied to the organic light emitting diode 300 of the display panel as the driving power from the first driver through the conductive line portion 600, the conductive connection portion, and the pad portion, and the organic light emitting diode 300 emits light by the first and second power.

Hereinafter, the sealing material 400, the pad portion 500, the conductive line portion 600, the conductive connection portion 700, and the first driver 800 will be described in further detail with reference to FIG. 1 and FIG. 2.

Referring again to FIG. 2 and FIG. 4, the sealing material 400 is sealed with the substrate 100, interposing the organic light emitting diode 300 therebetween, and includes a metal layer 410, an insulation layer 420, and an adhesive layer 430.

The metal layer 410 is arranged opposite to the organic light emitting diode 300 and includes a metal material such as nickel (Ni), steel (Fe), aluminum (Al), copper (Cu), chromium (Cr), silver (Ag), gold (Au), and tin (Sn). The metal layer 410 functions to prevent foreign articles (e.g., moisture) from being penetrated into the organic light emitting diode 300 from the outside.

The insulation layer 420 is disposed at the external side of the metal layer 410, and includes an insulating material such as resin. The insulation layer 420 prevents the metal layer 410, the conductive line portion 600, and the first driver 800 from being short-circuited.

The adhesive layer 430 is disposed between the substrate 100 and the metal layer 410, interposing the organic light emitting diode 300 therebetween, and seals the substrate 100 and the metal layer 410 along the substrate 100. The adhesive layer 430 includes thermosetting resin, and is in the state of being hardened by hardening means such as heat.

As shown in FIG. 2, the pad portion 500 is located corresponding to the edge 401 of the sealing material 400.

The pad portion 500 is disposed at the outer side of the sealing material 400 corresponding to the edge 401 of the sealing material 400, and is connected with the wire portion 200. The pad portion 500 may be formed simultaneously when the wire portion 200 is formed. The pad portion 500 includes a first sub-pad portion 510 and a second sub-pad portion 520 that are electrically connected with the organic light emitting diode 300.

As shown in FIG. 1, the first sub-pad portion 510 is provided in plural on the substrate 100, and the plurality of the first sub-pad portions 510 are disposed at a distance from each other corresponding to the entire edges 401 of the sealing material 400. The first sub-pad portions 510 are electrically connected with the first electrode of the organic light emitting diode, to which the first power is applied.

The second sub-pad portion 520 is provided in plural on the substrate 100, and the plurality of the second sub-pad portions 520 are disposed at a distance from each other corresponding to the entire edges 401 of the sealing material 400. The second sub-pad portions 520 are electrically connected with the second electrode of the organic light emitting diode, to which the second power is applied.

The plurality of the first sub-pad portions 510 and the plurality of the second sub-pad portions 520 are alternately arranged corresponding to the entire edges 401 of the sealing material 400. As described, the plurality of the first sub-pad portions 510 and the plurality of the second sub-pad portions 520 are alternately arranged corresponding to the entire edges 401 of the sealing material 400 such that the first power and the second power are uniformly supplied to the first and second electrodes respectively through the organic light emitting diode by the first sub-pad portions 510 and the second sub-pad portions 520.

As shown in FIGS. 1 and 2, the conductive line portion 600 is disposed on the sealing material 400, and the first and second power that are driving power supplied from the first driver 800 flow to the conductive line portion 600. The conductive line portion 600 is disposed between the first driver 800 and the conductive connection portion 700 over the entire upper surface of the sealing material 400. The conductive line portion 600 includes a conducting material such as copper (Cu), silver (Ag), and gold (Cu), and is formed on the insulation layer 420 of the sealing material 400. The conductive line portion 600 functions as a wire for transmitting the first power and the second power supplied from the first driver 800 respectively to the pad portion 500. The conductive line portion 600 includes a first sub-conductive line portion 610 and a second sub-conductive line portion 620.

The first sub-conductive line portion 610 is formed on the sealing material 400 and extended to a direction of the first sub-pad portion 510 from the first driver 800, and is connected with the first sub-pad portion 510 disposed on the substrate 100, interposing the conductive connection portion 700 therebetween. The first sub-conductive line portion 610 receives the first power that is the driving power from the first driver 800 and supplies the received power to the first sub-pad portion 510.

The second sub-conductive line portion 620 is formed on the sealing material 400 and then extended to a direction of the second sub-pad portion 520 from the first driver 800, and is connected with the second sub-pad portion 520 disposed on the substrate 100, interposing the conductive connection portion 700 therebetween. The second sub-conductive line portion 620 receives the second power that is the driving power from the first driver 800 and supplies the received power to the second sub-pad portion 520.

The conductive connection portion 700 directly connects the pad portion 500 and the conductive line portion 600. In further detail, the conductive connection portion 700 directly connects the first and second sub-pad portions 510 and 520 respectively formed on the substrate 100 and the first and second sub-conductive line portions 610 and 620 respectively formed on the sealing material 400 such that the conductive connection portion 700 is extended from the upper portion of the sealing material 400 to the upper portion of the substrate 100 through edges 401 of the sealing material 400. The conductive connection portion 700 is in the state of being hardened by a hardening means such as heat after being formed in the shape of conductive paste including a conductive material such as gold (Au), silver (Ag), and aluminum (Al) so as to be extended from the upper portion of the sealing member 400 to the upper portion of the substrate 100 through the edges 401 of the sealing member 400.

The first driver 800 is disposed on the sealing material 400 and connected with the first sub-conductive line portion 610 and the second sub-conductive line portion 620. The first driver 800 supplies the first power VDD (FIG. 3) that is the driving power of the organic light emitting diode 300 to the first sub-conductive line portion 610, and supplies the second power VSS (FIG. 3) that is the driving power of the organic light emitting diode 300 to the second sub-conductive line portion 620. The first power and the second power respectively supplied to the first sub-conductive line portion 610 and the second sub-conductive line portion 620 from the first driver 800 are respectively supplied to the first and second electrodes 310 and 330 (FIG. 4) of the organic light emitting diode 300 respectively through the respective conductive connection portions 700, the first sub-pad portion 510, and the second sub-pad portion 520. The first driver 800 may include a plurality of driving chips (IC), and a flexible printed circuit (FPC), and the flexible printed circuit may be electrically connected with the conductive line portion 600 by a tape carrier package. Further, the tape carrier package may respectively access the conductive line portion 600 and flexible printed circuit 100 using a connection member such as an anisotropic conductive film (ACF).

As described with respect to FIGS. 1-4, in the OLED display 1000 according to the first exemplary embodiment, the first power VDD and the second power VSS supplied to the organic light emitting diode 300 from the first driver 800 are respectively supplied through the entire area of the organic light emitting diode 300 corresponding to the edges 401 of the sealing member 400 through the conductive line portion 600, conductive connection portion 700, and pad portion 500 such that the same amount of driving power is supplied to a large-sized organic light emitting diode 300 of a large-sized OLED display 1000, and accordingly a failure such as a voltage drop due to resistance of the wire portion 200 or resistance of the organic light emitting diode 300 can be minimized. Accordingly, the organic light emitting diode 300 realizes an image with uniform luminance, thereby providing the OLED display 1000 with improved display quality.

In addition, in the OLED display 1000 according to the first exemplary embodiment, the first power VDD and the second power VSS that are driving power are supplied to the organic light emitting diode 300 through the conductive line portion 600, the conductive connection portion 700, and the pad portion 500 from one first driver 800 so that the driver may not need to be provided in plural. Accordingly, the number of drivers may not need to be increased even though the OLED display 1000 is increased in size. This is a main factor to reduce manufacturing time and manufacturing cost of the OLED display 1000.

As described, although the OLED display 1000 is increased in size, a sufficient amount of power can be supplied to the organic light emitting diode 300 and simultaneously the manufacturing time and manufacturing cost can be reduced according to the first exemplary embodiment.

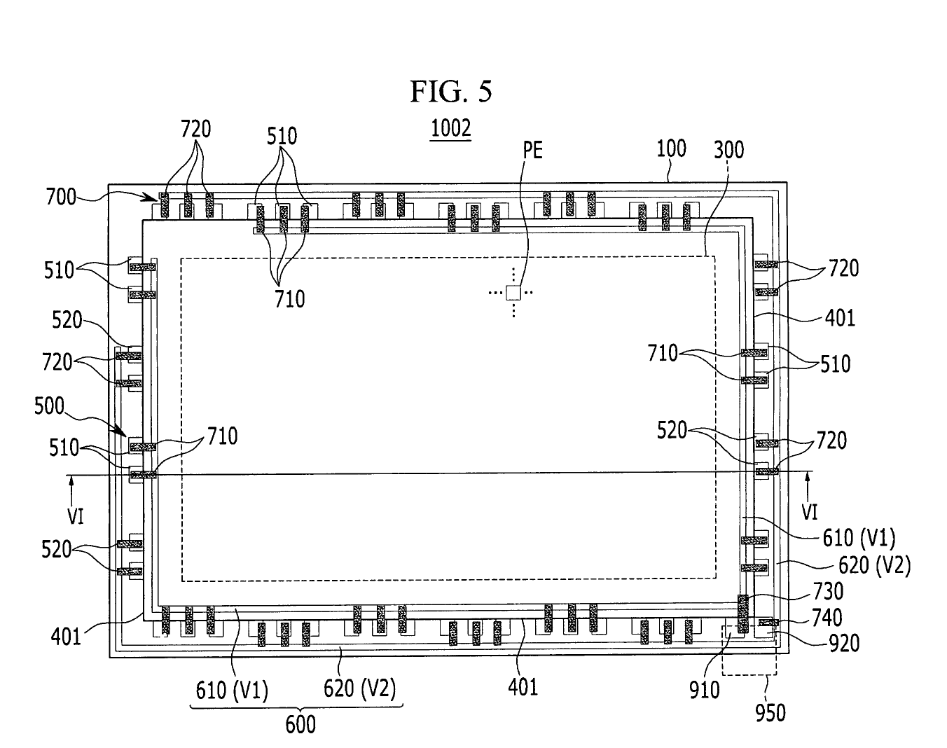

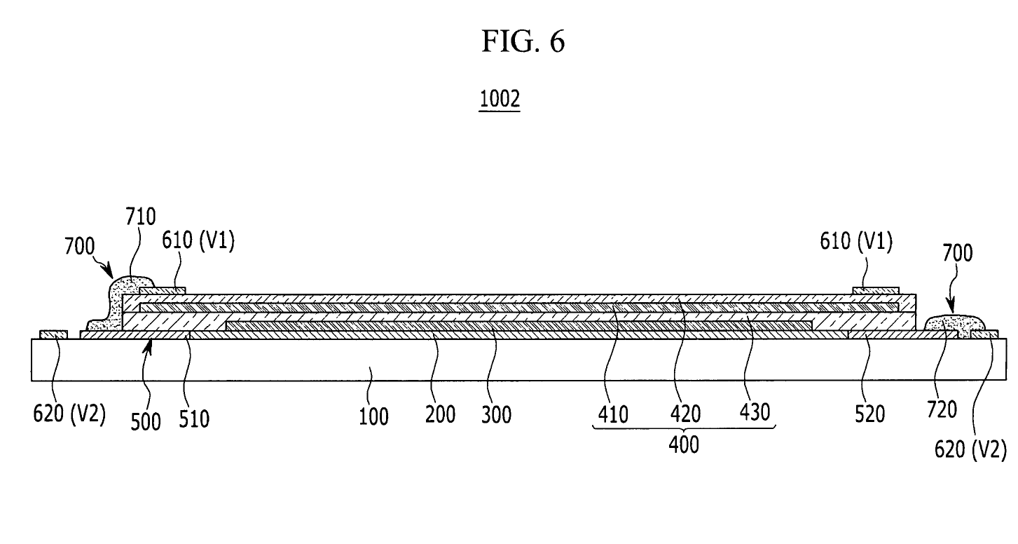

Hereinafter, an OLED display 1002 according to a second exemplary embodiment will be described with reference to FIG. 5 and FIG. 6.

# FIG. 5 is a top plan view of an OLED display 1002 according to the second exemplary embodiment. FIG. 6 is a cross-sectional view of FIG. 5, taken along the line VI-VI.

As shown in FIG. 5 and FIG. 6, the OLED display 1002 according to the second exemplary embodiment includes a substrate 100, a wire portion 200, an organic light emitting diode 300, a sealing material 400, a pad portion 500, a conductive line portion 600, a conductive connection portion 700, a first power supply portion 910, a second power supply portion 920, a second driver 950, and a plurality of pixels PE.

The sealing material 400 includes a metal layer 410, an insulation layer 420, and an adhesive layer 430.

The conductive line portion 600 includes a first sub-conductive line portion 610 and a second sub-conductive line portion 620. The conductive line portion 600 is selectively formed on the sealing material 400 and the substrate 100, and first power V1 (VDD) and second power V2 (VSS) that are driving power supplied from the second driver 950 flow to conductive line portion 600.

V2 The first sub-conductive line portion 610 is formed on the sealing material 400, and is connected with the first sub-pad portion 510 disposed on the substrate 100, interposing the conductive connection portion 700 therebetween. The first sub-conductive line portion 610 is extended along an edge of the sealing material 400, and receives the first power V1 through a first power supply portion 910 and the conductive connection portion 700 from the second driver 950 and supplies the received power to the first sub-pad portion 510.

The second sub-conductive line portion 620 is formed on the substrate 100, and is connected with the second sub-pad portion 520 formed on the substrate 100, interposing the conductive connection portion 700 therebetween. The second sub-conductive line portion 620 is extended along an edge of the substrate 100, and receives the second power V2 through a second power supply portion 920 and the conductive connection portion 700 from the second driver 950 and supplies the received power to the second sub-pad portion 520.

The conductive connection portion 700 includes a first sub-conductive connection portion 710, a second sub-conductive connection portion 720, a third sub-conductive connection portion 730, and a fourth sub-conductive connection portion 740.

The first sub-conductive connection portion 710 is extended from the first sub-conductive line portion 610 on the sealing material 400 to the sub-pad portion 510 on the substrate 100 through an edge 401 of the sealing material 400, and directly connects the first sub-conductive line portion 610 and the first sub-pad portion 510.

The second sub-conductive connection portion 720 is extended to the second sub-pad portion 520 from the second sub-conductive line portion 620 on the substrate 100, and directly connects the second sub-conductive line portion 620 and the second sub-pad portion 520.

The third sub-conductive connection portion 730 is extended to the first power supply portion 910 from the first sub-conductive line portion 610 on the sealing material 400, and directly connects the first sub-conductive line portion 610 and the first power supply portion 910.

The fourth sub-conductive connection portion 740 is extended to the second power supply portion 920 from the second sub-conductive line portion 620 on the substrate 100, and directly connects the second sub-conductive line portion 620 and the second power supply portion 920.

The first power supply portion 910 and the second power supply portion 920 are respectively disposed on the substrate 100 at the outer side of the sealing material 400, and respectively receive the first power V1 and the second power V2 from the second driver 950.

The second driver 950 accesses the first power supply portion 910 and the second power supply portion 920, and is connected with the first power supply portion 910 and the second power supply portion 920. The second driver 950 supplies the first power V1 that is driving power of the organic light emitting diode 300 to the first power supply portion 910, and supplies the second power V2 that is the driving power of the organic light emitting diode 300 to the second power supply portion 920. The first power V1 and the second power V2 respectively supplied to the first power supply portion 910 and the second power supply portion 920 from the second driver 950 are supplied to the first sub-conductive line portion 610 and the second sub-conductive line portion 620 through the third sub-conductive connection portion 730 and the fourth sub-conductive connection portion 740, and then supplied to the first sub-pad portion 510 and the second sub-pad portion 520 through the first sub-conductive connection portion 710 and the second sub-conductive connection portion 720 so as to be respectively supplied to a first electrode and a second electrode of the organic light emitting diode 300. The second driver 950 may include a plurality of driving chips (IC), and a flexible printed circuit (FPC), and the flexible printed circuit may be electrically connected with the first power supply portion 910 and the second power supply portion 920 by a tape carrier package. Further, the tape carrier package may respectively access the first power supply portion 910 and the second power supply portion 920 and flexible printed circuit 100 using a connection member such as an anisotropic conductive film (ACF).

As described, in the OLED display 1002 according to the second exemplary embodiment, the first power V1 and the second power V2 supplied from the second driver 950 to the organic light emitting diode 300 are uniformly supplied to the entire area of the organic light emitting diode 300 so that the same amount of driving power is supplied to a large-sized organic light emitting diode 300 of a large-sized OLED display 10002 and accordingly a failure such as a voltage drop due to resistance of the wire portion 200 or resistance of the organic light emitting diode 300 can be minimized. Accordingly, the organic light emitting diode 300 realizes an image with uniform luminance, thereby providing the OLED display 1002 with improved display quality.

In addition, in the OLED display 1002 according to the second exemplary embodiment, the first power V1 and the second power V2 that are driving power are supplied to the organic light emitting diode 300 through the conductive line portion 600, the conductive connection portion 700, and the pad portion 500 from one second driver 950 so that the driver may not need to be provided in plural. Accordingly, the number of drivers may not need to be increased even though the OLED display 1002 is increased in size. This is a main factor to reduce manufacturing time and manufacturing cost of the OLED display 1002.

As described, in the OLED display 1002 according to the second exemplary embodiment, a sufficient driving power can be supplied to the organic light emitting diode 300 even through the size of the organic light emitting diode 300 is increased, and simultaneously manufacturing time and manufacturing cost can be reduced.

While this disclosure has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. An organic light emitting diode (OLED) display comprising:
a substrate;
an organic light emitting diode disposed on the substrate;
a sealing member sealed with the substrate, interposing the organic light emitting diode therebetween;
a pad portion disposed on the substrate, corresponding to an edge of the sealing member, and electrically connected with the organic light emitting diode;
a first conductive line portion formed on the sealing member, and applied with driving power supplied to the organic light emitting diode; and
a conductive connection portion directly connecting the pad portion and the first conductive line portion.

2. The OLED display of claim 1, wherein the organic light emitting diode comprises:
a first electrode disposed on the substrate;
an organic emission layer disposed on the first electrode; and
a second electrode disposed on the organic emission layer, and
the pad portion comprises:
a first sub-pad portion electrically connected with the first electrode, and
a second sub-pad portion electrically connected with the second electrode.

3. The OLED display of claim 2, wherein the first pad-portion and the second par-portion are respectively provided in plural, and the plurality of first sub-pad portions and the plurality of second sub-pad portions respectively alternate each with other in arrangement corresponding to the entire edges of the sealing member.

4. The OLED display of claim 2, wherein the first electrode is light transflective and the second electrode is light reflective.

5. The OLED display of claim 2, wherein the first conductive line portion comprises
a first sub-conductive line portion connected with the first sub-pad portion, interposing the conductive connection portion therebetween, and
a second sub-conductive line portion connected with the second sub-pad portion, interposing the conductive connection portion therebetween.

6. The OLED display of claim 5, wherein the first sub-conductive line portion and the second sub-conductive line portion are formed on the sealing member, and the conductive connection portion is extended to the upper portion of the substrate from the sealing member through an edge of the sealing member.

7. The OLED display of claim 6, further comprising a driver disposed on the sealing member and being connected with the first and second sub-conductive line portions, supplying first power as the driving power to the first sub-conductive line portion, and supplying second power as the driving power to the second sub-conductive line portion.

8. The OLED display of claim 5, wherein the organic light emitting diode further comprises a second conductive line portion formed on the substrate.

9. The OLED display of claim 8, wherein the first conductive line portion comprises a first sub-conductive line portion connected with the first sub-pad portion, interposing the conductive connection portion therebetween, and
the second conductive line portion comprises a second sub-conductive line portion connected with the second sub-pad portion, interposing the conductive connection portion therebetween.

10. The OLED display of claim 9, wherein the conductive connection portion comprises:
a first sub-conductive connection portion extended to the upper portion of the substrate through an edge of the sealing member from the sealing member and connecting the first sub-conductive line portion and the first sub-pad portion; and
a second sub-conductive connection portion connecting the second sub-conductive line portion and the second sub-pad portion on the substrate.

11. The OLED display of claim 10, further comprising:
a first power supply portion disposed on the substrate;
a second power supply portion disposed on the substrate; and
a driver supplying first power as driving power to the first power supply portion and supplying second power as driving power to the second power supply portion,
wherein the conductive connection portion further comprises a third sub-conductive connection portion extended to the upper portion of the substrate from the sealing member through an edge of the sealing member and connecting the first sub-conductive line portion and the first power supply portion, and a fourth sub-conductive connection portion connecting the second sub-conductive line portion and the second power supply portion on the substrate.

12. The OLED display of claim 1, wherein the sealing member comprises:
a metal layer disposed on the organic light emitting diode;
an insulation layer disposed between the metal layer and the first conductive line portion; and
an adhesive layer disposed between the metal layer and the organic light emitting diode.

13. The OLED display of claim 11, wherein the sealing member comprises:
a metal layer disposed on the organic light emitting diode;
an insulation layer disposed between the metal layer and the conductive line portion; and
an adhesive layer disposed between the metal layer and the organic light emitting diode.
